(19) United States
(12) Patent Application Publication
(10) Pub. No.: US 2015/0372251 A1
(43) Pub. Date: Dec. 24, 2015

(54) ELECTRIC ELEMENT PACKAGE

(71) Applicant: Toshishige Fujii, Kanagawa (JP)

(72) Inventor: Toshishige Fujii, Kanagawa (JP)

(21) Appl. No.: 14/731,946

(22) Filed: Jun. 5, 2015

(30) Foreign Application Priority Data
Jun. 19, 2014 (JP) 2014-126280

(51) Int. Cl. H01L 51/52; H01L 51/00

(52) U.S. Cl. CPC H01L 51/524; H01L 51/5215; H01L 51/5234; H01L 51/0096; H01L 2251/308; H01L 2251/301

(57) ABSTRACT

An electric element package is provided including an electrode formed on an element substrate and made of alloy whose main component is Al or Ag, an ITO layer formed on the electrode, an electric element formed on the electrode, a sealing substrate arranged so as to face the element substrate, and a glass frit formed between the sealing substrate and the ITO layer, the glass fit having a portion that contacts the ITO layer and a portion that contacts the sealing substrate, where the portion of the glass frit that contacts the ITO layer has width that is 50 to 80 percent of the portion of the glass frit that contacts the sealing substrate.

### CROSS-REFERENCE TO RELATED APPLICATION

This patent application is based on and claims priority pursuant to 35 U.S.C. §119(a) to Japanese Patent Application No. 2014-126280, filed on Jun. 19, 2014, in the Japan Patent Office, the entire disclosure of which is hereby incorporated by reference herein.

### BACKGROUND

1. Technical Field

Example embodiments relate to an electric element package.

2. Background Art

In recent years, various types of research and development have been conducted for displays (organic electroluminescence (EL) display) where organic EL elements are used as electric elements. It is known in the art that such organic EL elements (organic EL layers) are sensitive and thus easily deteriorated when exposed to oxygen or moisture in ambient environment.

Accordingly, the maintenance and prolongation of life spans of the display quality are achieved by integrating a hermetically-sealed organic EL layer into an organic EL display. In order to fabricate an organic EL element package where an organic EL layer is hermetically sealed, firstly, a sealing substrate is arranged above an element substrate on which an organic EL element is disposed, with allowing space therebetween. Then, the space between the sealing substrate and the element substrate is hermetically sealed by glass frit so as to encompass the periphery of the organic EL layer arranged on the element substrate. In so doing, it is known in the art that laser beam is emitted via the sealing substrate to heat the glass frit. By so doing, the glass frit is softened and liquidized, and the element substrate 3 and the sealing substrate 4 are sealed together. Accordingly, hermetically-sealed structure is achieved.

However, when a glass frit is irradiated with laser beam, an electrode (for example, an indium-tin oxide (ITO) electrode) that externally supplies power to an organic EL layer may be damaged or broken. It is considered that the cause of such damage or breakage is the heat produced by the irradiation of laser beam or the contact between the electrode and the glass frit.

More specifically, an electrode that externally supplies power to an organic EL layer is disposed below the glass frit. When the glass frit is irradiated with laser beam, the glass frit absorbs the optical energy, and transforms the absorbed optical energy into heat. Then, the heat is passed to the electrode disposed under the glass frit, and the glass frit is softened and liquidized due to the heat and contacts the electrode. It is considered that damage on the electrodes are caused by the phenomenon described above.

For the above reasons, in the production of organic EL element packages, the heat produced by the irradiation of laser beam needs to be suppressed, and the contact between the electrode and the glass fit needs to be avoided. For example, it is known in the art that a substrate on which an organic EL element is disposed and a facing substrate are sealed by providing glass frit upon disposing a pile of a metallic layer and a metallic oxide layer or metal nitride layer on the substrate on which an organic EL element is disposed. By so doing, when the glass frit is irradiated with laser beam, the laser beam is reflected on the metallic layer.

However, the glass frit is directly welded onto the metallic layer that reflects laser beam, the adhesive strength between the glass frit and the metallic layer cannot sufficiently be maintained. For this reason, it is necessary to have a metallic oxide layer or a metal nitride layer between the metallic layer and the glass frit. When the metallic layer contacts the electrode that is connected to the organic EL element, it is also necessary to have insulating layer between the metallic layer and the electrode in order to insulate the metallic layer from the electrode.

It is to be noted that such configuration lowers the degree of flexibility in the design of organic EL element packages.

Moreover, the provision of insulative metallic oxide is not sufficient to prevent the damage on electrodes, and breakage or an increase in resistance value may still occur. It is to be noted that such provision of an insulating layer lowers the degree of flexibility in the design of organic EL element packages.

### SUMMARY

Embodiments of the present invention described herein provide an electric element package including an electrode formed on an element substrate and made of alloy whose main component is Al or Ag, an ITO layer formed on the electrode, an electric element formed on the electrode, a sealing substrate arranged so as to face the element substrate, and a glass frit formed between the sealing substrate and the ITO layer, the glass fit having a portion that contacts the ITO layer and a portion that contacts the sealing substrate. In the electric current package, the portion of the glass frit that contacts the ITO layer has width that is 50 to 80 percent of the portion of the glass frit that contacts the sealing substrate.

### BRIEF DESCRIPTION OF THE DRAWINGS

A more complete appreciation of exemplary embodiments and the many attendant advantages thereof will be readily obtained as the same becomes better understood by reference to the following detailed description when considered in connection with the accompanying drawings.

FIG. 1 is a schematic diagram of an electric element package according to an example embodiment of the present invention.

FIG. 2 is a magnified view of a schematic diagram of an electric element package according to an example embodiment of the present invention.

FIG. 3 is a magnified view of a schematic diagram of an electric element package according to another example embodiment of the present invention.

FIG. 4 is a magnified view of a schematic diagram of an electric element package according to another example embodiment of the present invention.

FIG. 5 is a schematic diagram used to describe the welding of a sealing substrate in an electric element package according to an example embodiment of the present invention.

FIG. 6 illustrates the relationship between the rate of welded portion in width and resistance value in an electric element package according to an example embodiment of the present invention.

FIG. 7 illustrates the relationship between the rate of welded portion in width and resistance value in an electric element package according to another example embodiment of the present invention.

FIG. 8 illustrates the relationship between the ITO thickness/electrode thickness and resistance value in an electric element package according to an example embodiment of the present invention.

FIG. 9 illustrates the relationship between the ITO thickness/electrode thickness and resistance value in an electric element package according to another example embodiment of the present invention.

The accompanying drawings are intended to depict exemplary embodiments of the present disclosure and should not be interpreted to limit the scope thereof. The accompanying drawings are not to be considered as drawn to scale unless explicitly noted.

### DETAILED DESCRIPTION

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

In describing example embodiments shown in the drawings, specific terminology is employed for the sake of clarity. However, the present disclosure is not intended to be limited to the specific terminology so selected and it is to be understood that each specific element includes all technical equivalents that have the same structure, operate in a similar manner, and achieve a similar result.

An electric element package according to an example embodiment of the present invention is described below with reference to the drawings. Embodiments of the present invention has been described above, but the present invention is not limited to those embodiments and various applications and modifications may be made without departing from the scope of the invention. In the following description, an organic EL element package that is integrated into an organic EL display is described as an example of an electric element package.

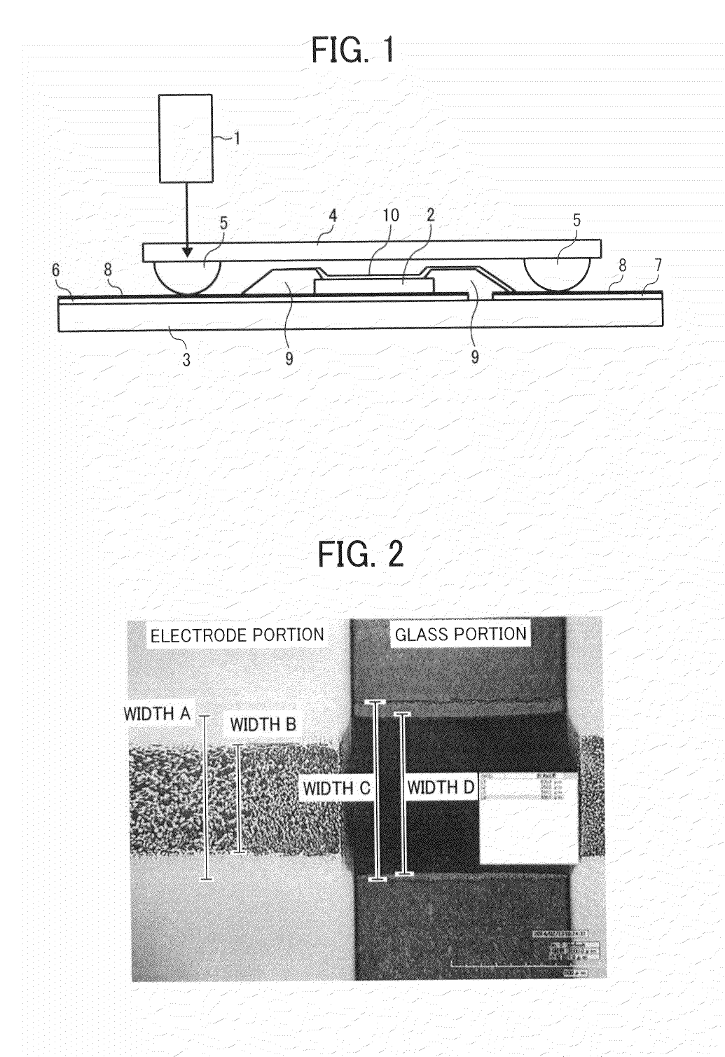

FIG. 1 is a schematic diagram of an electric element package according to an example embodiment of the present invention. FIG. 1 is a schematic vertical section of an organic EL element package according to an example embodiment of the present invention, including a laser irradiator 1, an organic electroluminescence (EL) layer 2, an element substrate 3, a sealing substrate 4, a glass frit 5, a first electrode 6, a second electrode 7, an indium-tin oxide (ITO) layer 8, a bank 9, and a surface electrode 10. As illustrated in FIG. 1, the organic EL layer 2 is formed on the element substrate 3, and the sealing substrate 4 is arranged so as to face the element substrate 3 having the organic EL layer 2 therebetween with certain space. The glass frit 5 seals the space between the element substrate 3 and the sealing substrate 4, while encompassing the periphery of the organic EL layer 2 in a frame-like shape. Note that it is not always necessary for the glass frit 5 to encompass the periphery of the organic EL layer 2 in the present example embodiment, but it is desired that the glass frit 5 encompass the periphery of the organic EL layer 2.

The element substrate 3 and the sealing substrate 4 may be made of any known material, and no limitation is intended. For example, the element substrate 3 and the sealing substrate 4 may be made of glass with the thickness of 0.05 to 2 mm. The first electrode 6 and the second electrode 7 are formed on the element substrate 3, and the ITO layer 8 is further formed on the first electrode 6 and the second electrode 7, respectively.

Moreover, the organic EL layer 2 is formed on the first electrode 6, and the bank 9 is formed to insulate the first electrode 6 from the second electrode 7. The bank 9 may be made of any known material, and no limitation is intended. For example, the bank 9 may be made of polyimide. Further, the surface electrode 10 is arranged above the top surface of the bank 9 and the organic EL layer 2 to achieve the conductivity with the second electrode 7.

The first electrode 6 and the ITO layer 8 run through the bottom of the glass frit 5, and are guided to the outside of the organic EL element package. Accordingly, power is supplied to the organic EL layer 2 through the first electrode 6 and the ITO layer 8. Note that the first electrode 6 and the ITO layer 8 are branched according to prescribed patterns.

No limitation is intended, but the materials that are used for the organic EL layer 2 include, for example, tris(8-hydroxyquinolinato)aluminium complex (Alq₃), bis(benzoquinolinolato)beryilium complex (BeBq), tris(dibenzoylmethane)(monophenanthroline)europium(III) complex (Eu(DBM)₃(phen)), or 4,4′-bis(2,2-diphenylvinyl)-1,1′-biphenyl (DTVBi). No limitation is intended, but it is desired that the film thickness of the organic EL layer 2 be 50 to 80 nm.

Note that an electron injection layer, an electron transport layer, a hole transport layer, a hole injection layer, or the like may be formed above and under the organic EL layer 2 as desired. The these layers may be made of any known material, and no limitation is intended. The film thickness of these layers may be varied as desired, and no limitation is intended.

The first electrode 6 and the second electrode 7 according to the present the present example embodiment are made of alloy whose main component is aluminum (Al) or silver (Ag). When the main component is Al or Ag, the optical property improves. In particular, the transmittance increases. The first electrode 6 and the second electrode 7 may be made of the same material, or may be made of different materials. Hereinafter, the first electrode 6 and the second electrode 7 may be referred to simply as electrodes.

It is desired that the electrodes be made of alloy including aluminum (Al), silicon (Si), and copper (Cu), and alloy including silver (Ag), palladium (Pd), and copper (Cu). With Si, Pd, and Cu, the lightfastness and fade resistance improve, and the bondability with the substrate is enhanced. Accordingly, high reliability is achieved. It is desired that Al or Ag be included in the electrodes with the weight ratio of 95 to 99 percent.

When the alloy includes Al, Si, and Cu, it is desired that Si and Cu be included in the electrodes with the weight ratio of 0.5 to 3.0 percent and 0.1 to 3.0 percent, respectively. When such content by percentage is satisfied, it becomes possible for electrodes to have high conductivity and become corrosion-resistant. Further, both high reflectivity and environmental resistance are achieved, and the electrodes can be prevented from coming off from the substrate. When Si or Cu is included in the electrodes with weight ratio of 3.0 percent or greater, the reflectivity declines sharply, and the brightness of organic EL element decreases.

When the alloy includes Ag, Pd, and Cu, it is desired that Pd and Cu be included in the electrodes with the weight ratio of 0.5 to 3.0 percent and 0.1 to 3.0 percent, respectively. When such content by percentage is satisfied, it becomes possible for electrodes to have high conductivity and become corrosion-resistant. Further, both high reflectivity and environmental resistance are achieved, and the electrodes can be prevented from coming off from the substrate. When Pd or Cu is included in the electrodes with weight ratio of 3.0 percent or greater, the reflectivity declines sharply, and the brightness of organic EL element decreases.

As electrodes are made of alloy whose main component is Al or Ag, for example, AlSi alloy thin film or AgPd alloy thin film may be used for the electrodes. However, a black stain may appear when Si or Pd is included in the electrodes with weight ratio of 2.5 to 4.5 percent. When such a black stain is observed using a microscope, it is observed that there are bulges in a minute area. By contrast, when AlSiCu alloy thin film or AgPdCu alloy thin film is used, the occurrence of black stains can be prevented as long as the desired content by percentage as mentioned above is satisfied.

While the ITO layer 8 is formed on a portion of the electrodes or all over the electrodes, it is necessary for the glass frit 5 to touch the ITO layer. When this requirement is not satisfied, the electrodes are damaged by heat when the glass frit 5 is sealed by laser and electrodes are heated. It is desired that the electrodes have the film thickness of 100 to 200 nm.

Another layer may be formed between the organic EL layer 2 and the first electrode 6, or no layer may be formed therebetween. No limitation is intended, but the ITO layer 8, a different kind of transparent electrode, a protection layer, the electron injection layer, the electron transport layer, the hole transport layer, the hole injection layer, or the like may be formed between the organic EL layer 2 and the first electrode 6. In particular, it is desired that the ITO layer 8 be formed between the organic EL layer 2 and the first electrode 6. Due to the provision of the first electrode 6 as above, the potential barrier is attenuated, and electron injection to the organic EL layer 2 becomes easier.

It is desired that the ITO layer 8 have the film thickness that is 5 to 15 percent of the thickness of the electrodes. In particular, 7 to 10 percent of the thickness of the electrodes is desired. When such ranges are satisfied, a sufficiently low resistance value and high reliability are both achieved. When the thickness of the electrodes is, for example, 150 nm, it is desired that the ITO layer 8 have the film thickness of 7.5 to 22.5 nm. In particular, 10 to 15 nm is desired.

When the film thickness of the ITO layer 8 is less than 5 percent of the thickness of the electrodes, the reliability decreases, and the electrodes may become broken or the resistance value may increase. On the other hand, when the film thickness of the ITO layer 8 is greater than 15 percent, the resistance value in the conductivity with the outside cannot be lowered due to the high resistance value of ITO in comparison to alloy electrodes. Further, exfoliation may occur due to the stress difference among the electrodes, the ITO layer 8, and the glass frit 5.

No limitation is intended, but it is desired that the surface electrode 10 be a transparent electrode. In particular, it is desired that the surface electrode 10 be made of ITO. Alternatively, for example, tin oxide or zinc oxide may be used for the surface electrode 10. When the surface electrode 10 is a film of transparent electrode as described above, the light from the organic EL layer 2 can be emitted to the upper side of FIG. 1. It is desired that the surface electrode 10 have the film thickness of 100 to 200 nm.

As illustrated in FIG. 1, the hermetically sealed structure of an organic EL element package is achieved by emitting the laser beam from the laser irradiator 1 to the glass frit 5 via the sealing substrate 4, and by heating the glass frit 5 to soften and liquidize such that the element substrate 3 and the sealing substrate 4 are sealed together.

No limitation is indicated, but for example, “Integra” manufactured by Spectra-Physics, Inc. may be used as the laser irradiator 1. No limitation is intended, but for example, a near-infrared semiconductor laser with the wavelength of 800 to 1100 nm may be used as the laser beam emitted from the laser irradiator 1.

In the present example embodiment, the glass frit 5 that contacts the ITO layer 8 has the width that is 50 to 80 percent of the glass frit 5 that contacts sealing substrate 4. By arranging the conditions such that a glass frit melts due to laser irradiation and the welding with the element substrate 3 has the width that is 50 to 80 percent of the frit width on the sealing substrate 4 side, highly-reliable sealing with sufficient adhesive strength is achieved without damage on the electrodes (breakage or increase in resistance value).

In the present example embodiment, the ratio of the width of the welding of a glass frit molten due to laser irradiation with the element substrate 3 to the frit width on the sealing substrate 4 side may be referred to as a rate of welded portion in width.

In the present example embodiment, the width of the glass frit 5 is measured by an optical microscope. More specifically, several widths of the glass frit 5 are measured, and the mean value of the measured widths is calculated. The number of widths to be measured is not limited when a mean value is calculated, but it is desired that about five to ten widths be measured to calculate a mean value. Note that commercially available image processing software may be used to measure widths.

FIG. 2 is an example micrograph of the organic EL element package of FIG. 1 observed from the underside. Although FIG. 2 is an example photograph of the welded portion of the glass fit 5, the rate of welded portion in width is eighty-six percent and thus the example illustrated in FIG. 2 does not fall under the present example embodiment of the present invention.

The glass portion of the element substrate 3 is captured on the right side of FIG. 2, and the glass frit 5 and the welded portion of the element substrate 3 (black portion) are observed through the glass in the horizontal direction (surface direction of the substrate). The rate of welded portion in width is the ratio of the width of the glass frit 5 (width C) and the width of the welded portion in black (width D). In FIG. 2, the rate of welded portion in width, i.e., width D/width C, is 86 percent.

The welding portion of the electrodes (the first electrode 6 or the second electrode 7) is observed on the left side of FIG. 2. As FIG. 2 is an example micrograph of the element substrate 3 observed from the underside, it is hard to see the glass frit 5 due to metallic reflection. However, trace of welding whose width is about the same as the welding width (width D) on the glass plane of the element substrate 3 is observed in the electrode portion. The trace of the welding is indicated by width A in FIG. 2.

In FIG. 2, as the welding power for the glass fit 5 is strong in the organic EL element package and the rate of welded portion in width is as large as eighty-six percent, it is observed that the color of the welded portions of the electrodes is turned to black. The portions of the electrodes whose color is turned to black is indicated by width B in FIG. 2. Note that the ratio of the width B to the width of the glass frit 5 (width C) is about sixty percent.

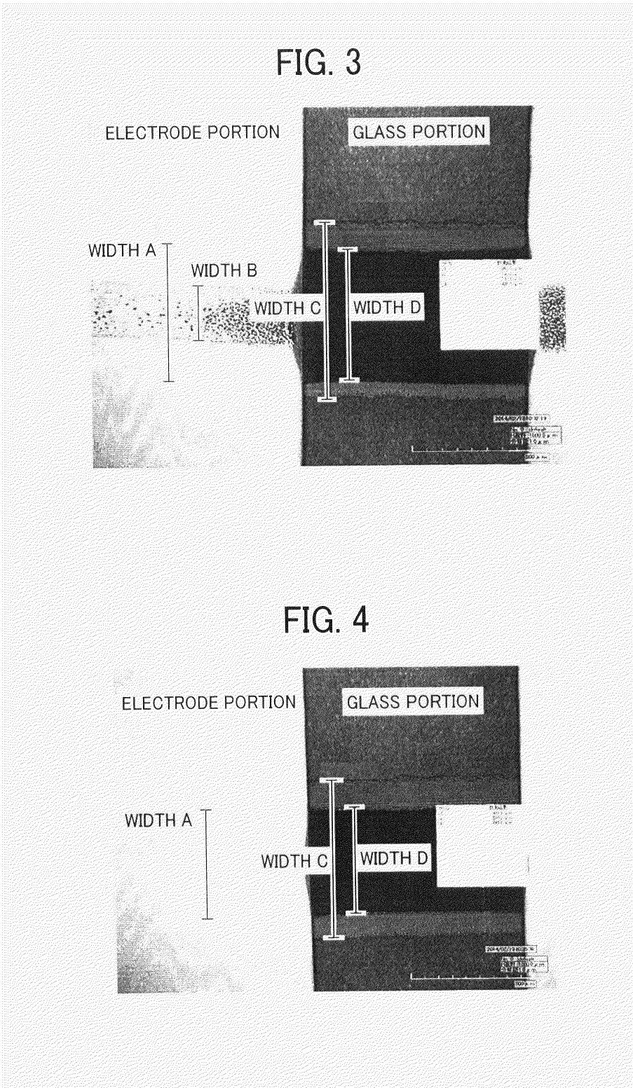

FIG. 3 is another example micrograph of the organic EL element package of FIG. 1 observed from the underside. In a similar manner to FIG. 2, FIG. 3 is an example photograph of the welded portion of the glass fit 5. The rate of welded portion in width is seventy-four percent and thus the example illustrated in FIG. 3 falls under the present example embodiment of the present invention. In FIG. 3, the ratio of the width B where the color of the electrode is turned to black to the width of the glass frit 5 (width C) is about thirty-one percent, and the degree of discoloration is smaller than that of FIG. 2. Note that FIG. 3 indicates an example where the welding power for the glass frit 5 in the organic EL element package is smaller than that of FIG. 2.

FIG. 4 is another example micrograph of the organic EL element package of FIG. 1 observed from the underside. In a similar manner to FIG. 2, FIG. 4 is an example photograph of the welded portion of the glass fit 5. The rate of welded portion in width is sixty-six percent and thus the example illustrated in FIG. 4 falls under the present example embodiment of the present invention. In FIG. 4, no width B is observed where the color of the electrode is turned to black, which is preferable. Note that FIG. 4 indicates an example where the welding power for the glass frit 5 in the organic EL element package is smaller than that of FIG. 2.

No limitation is intended, but the rate of welded portion in width may be controlled to within fifty to eighty percent, for example, by controlling the welding power the welding power of the laser welding for the glass frit 5, or by controlling the scanning speed of the laser welding. Although the welding power may vary due to other conditions such as scanning speed, it is desired that the welding power be 15 to 25 mW. When the welding power is too strong, the color of the electrode may be turned to black as illustrated in FIG. 2. On the other hand, when the welding power is too weak, the glass frit 5 cannot sufficiently be sealed. Although the scanning speed of welding may vary due to other conditions, it is desired that the scanning speed be 1 to 3 cm/s. When the scanning speed is too slow, the tact becomes slow, and the color of the electrode may be turned to black as illustrated in FIG. 2. On the other hand, when the scanning speed is too fast, the glass frit 5 cannot sufficiently be sealed.

Next, a method of sealing the glass frit 5 to the element substrate 3 and the sealing substrate 4 is described. Firstly, paste-like glass frit 5 is applied to the periphery of the sealing substrate 4. No limitation is intended, but the glass frit 5 may be applied, for example, by performing dispensing or screen printing.

No limitation is intended, but the glass frit 5 may be, for example, a mixture of: glass fit whose main components are zinc oxide (ZnO), bismuth oxide (Bi₂O₃), phosphoric acid (P₂0₅), or the like; resin fine particles such as polyethylene, urethane, acryl, or the like; refractory filler such as alumina (Al₂O₃), silica (SiO₂); and solvent such as terpineol.

No limitation is intended, but when the paste-like glass frit 5 is applied to the periphery of the sealing substrate 4, the thickness and width vary depending, for example, on the size of the substrate and the material of the glass frit 5. For example, the thickness may be set to 10 to 40 micrometers, and the width may be set to 500 to 800 millimeters.

Secondly, the entirety of the sealing substrate 4 is heated in an electric furnace, to dry up and burn the sealing substrate 4. Then, the resin components and the solvent components in the paste are decomposed and evaporated, to harden the glass frit 5 on a temporary basis. No limitation is intended, but the temperature and the length of time for the above processing may be, for example, about 400 degree Celsius and one hour, respectively. The burnt glass frit 5 has the thickness of for example, 5 to 20 micrometers.

The element substrate 3 and the sealing substrate 4 as obtained above are bonded together under the inert-gas atmosphere, and the glass frit 5 is irradiated with laser beam through the sealing substrate 4. No limitation is intended, but the inert gas may be, for example, argon (Ar). As irradiated with laser beam, the glass frit 5 melts and gets softened and liquidized, and the glass frit 5 can directly be welded onto the element substrate 3. Accordingly, the element substrate 3 and the sealing substrate 4 are bonded together along the periphery of the sealing substrate 4, and the organic EL layer 2 can be hermetically sealed.

### EXAMPLES

Hereinafter, the present invention is described with reference to examples and control samples. Note that the present invention is not limited to the examples described below.

### First Example

A glass insulative substrate with the dimension of 40 mm*40 mm and the thickness of 0.7 mm was used as the element substrate 3, and the first electrode 6 and the second electrode 7 that are made of aluminium-silicon-copper (Al—Si—Cu) alloys (with the composition of Al:Si:Cu=98:1:1) were pattern-formed by sputtering on the element substrate 3 with the film thickness of 150 nm. Next, the ITO layer 8 is formed by sputtering with the film thickness of 15 nm, so as to shield the first electrode 6 and the second electrode 7 with the patterns same as those of the first electrode 6 and the second electrode 7. Then, a light-emitting material Alq3 is pattern-formed on the ITO layer 8 by mask vapor deposition, to form the organic EL layer 2 with the film thickness of 65 nm. Next, α-NPD of 60 nm is formed by vapor deposition as a hole injection layer. On the hole injection layer, certain patterns of ITO are formed by mask vapor deposition so as to be connected to the second electrode 7. As a result, the surface electrode 10 with the film thickness of 100 nm is formed.

Next, an insulative substrate that is made of glass with the dimension of 26 mm*40 mm and the thickness of 0.7 mm is used as the sealing substrate 4, and the paste-like glass frit 5 is applied to the periphery of the sealing substrate 4 by a screen printing machine with the thickness of 40 micrometers and the width of 0.6 millimeters. Here, the paste of bismuth oxide whose glass transition temperature is 410 degrees used as the paste-like glass frit 5. Then, the resin components and the solvent components in the paste are dried up and burnt at 450 degree Celsius for one hour so as to be decomposed and evaporated. Accordingly, the paste-like glass frit 5 is firmly fixed to the sealing substrate 4. The height of the burnt glass frit 5 was 15 micrometers. After that, the entirety of the sealing substrate 4 was heated in an electric furnace at 400 degree Celsius for one hour, to harden the glass frit 5 on a temporary basis.

Next, the element substrate 3 and the sealing substrate 4 as obtained above are bonded together under the inert-gas (Ar gas) atmosphere, and the glass frit 5 is irradiated with laser beam through the sealing substrate 4 under the following welding conditions so as to melt, and soften and liquidize the glass frit 5. Accordingly, the glass frit 5 is directly welded to the element substrate 3 and the element substrate 3 and the sealing substrate 4 are bonded together along the periphery of the sealing substrate 4, and the organic EL layer 2 can be hermetically sealed. The organic EL element package according to the first example was obtained as described above.

[Welding Conditions]
Device Name: INTEGRA (manufactured by Spectra-Physics, Inc.)
Wavelength of Semiconductor Laser: 808 nm
Scanning Speed of Laser Welding: 2 cm/s
Welding Power: 23 mW

The micrograph of the organic EL element package obtained in the first example appeared like the micrograph of FIG. 3, and the rate of welded portion in width was found to be 74 percent. Note that the micrograph was analyzed by using image processing software and the mean value of the values measured from about ten portions is calculated to calculate the rate of welded portion in width.

### Second Example

An organic EL element package was produced in a similar manner to the first example described above, except that the first electrode 6 and the second electrode 7 are made of AgPdCu alloys instead of Al—Si—Cu alloys. Here, the composition of the AgPdCu alloys was Ag:Pd:Cu=98:1:1. The micrograph of the organic EL element package obtained in the second example appeared like the micrograph of FIG. 3, and the rate of welded portion in width was found to be 75 percent.

### Third Example

An organic EL element package was produced in a similar manner to the first example described above, except that the welding power, which is one of the welding conditions of the glass fit 5, is changed from 23 mW to 20 mW. The micrograph of the organic EL element package obtained in the third example appeared like the micrograph of FIG. 4, and the rate of welded portion in width was found to be 66 percent.

### Fourth Example

An organic EL element package was produced in a similar manner to the second example described above, except that the welding power, which is one of the welding conditions of the glass fit 5, is changed from 23 mW to 20 mW. The micrograph of the organic EL element package obtained in the fourth example appeared like the micrograph of FIG. 4, and the rate of welded portion in width was found to be 63 percent.

[First Control Sample]

An organic EL element package was produced in a similar manner to the first example described above, except that the welding power, which is one of the welding conditions of the glass fit 5, is changed from 23 mW to 26 mW. The micrograph of the organic EL element package obtained in the first control sample appeared like the micrograph of FIG. 2, and the rate of welded portion in width was found to be 86 percent.

[Second Control Sample]

An organic EL element package was produced in a similar manner to the second example described above, except that the welding power, which is one of the welding conditions of the glass fit 5, is changed from 23 mW to 26 mW. The micrograph of the organic EL element package obtained in the second control sample appeared like the micrograph of FIG. 2, and the rate of welded portion in width was found to be 83 percent.

[Third Control Sample]

An organic EL element package was produced in a similar manner to the first example described above, except that the welding power, which is one of the welding conditions of the glass fit 5, is changed from 23 mW to 13 mW. The rate of welded portion in width of the organic EL element package obtained in the third control sample was found to be 47 percent. In the organic EL element package obtained in the third control sample, the adhesive strength was weak, and the sealing by the glass fit 5 was insufficient.

[Fourth Control Sample]

An organic EL element package was produced in a similar manner to the second example described above, except that the welding power, which is one of the welding conditions of the glass frit 5, is changed from 23 mW to 13 mW. The rate of welded portion in width of the organic EL element package obtained in the fourth control sample was found to be 48 percent. In the organic EL element package obtained in the fourth control sample, the adhesive strength was weak, and the sealing by the glass frit 5 was insufficient.

### Fifth Example

An organic EL element package was produced in a similar manner to the first example described above, except that the first electrode 6 and the second electrode 7 are made of AlSi alloys instead of Al—Si—Cu alloys. Here, the composition of the AlSi alloys was Al:Si=98.5:1.5. The micrograph of the organic EL element package obtained in the fifth example appeared like the micrograph of FIG. 3, and the rate of welded portion in width was found to be 75 percent. It was possible to use the organic EL element package obtained in the fifth example, but the electrical-resistance value was slightly higher than that obtained in the first example, and the organic EL element package obtained in the fifth example was inferior in fade resistance.

### Sixth Example

An organic EL element package was produced in a similar manner to the first example described above, except that the first electrode 6 and the second electrode 7 are made of AgPd alloys instead of Al—Si—Cu alloys. Here, the composition of the AgPd alloys was Ag:Pd=98.5:1.5. The micrograph of the organic EL element package obtained in the sixth example appeared like the micrograph of FIG. 3, and the rate of welded portion in width was found to be 76 percent. It was possible to use the organic EL element package obtained in the sixth example, but the electrical-resistance value was slightly higher than that obtained in the first example, and the organic EL element package obtained in the fifth example was inferior in fade resistance.

[Resistance Value Experiment 1]

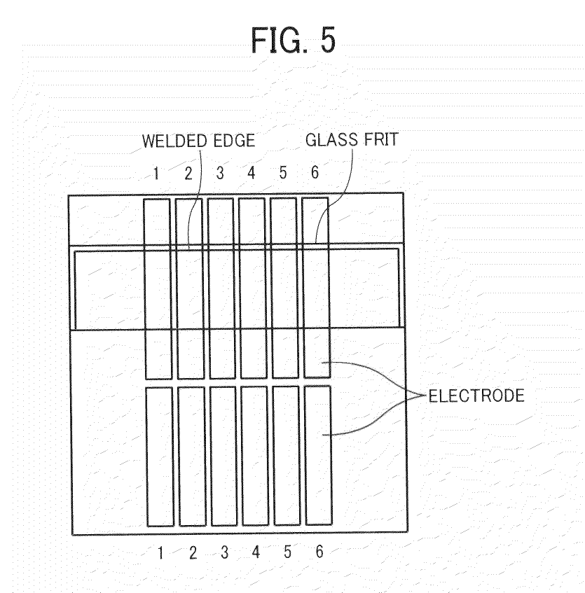

In order to investigate how much the resistance of electrodes varies due to welding, a cell was produced as illustrated in FIG. 5 as in the following steps. Six first electrodes 6 each of which was similar to the first electrode 6 used in the first example were fabricated on a top-half of the cell and on a bottom-half of the cell, respectively. One piece of glass frit 5 was welded so as to run across the first electrodes 6 on the top half. Note that the glass frit 5 used herein was similar to that of the first example, and the welding of the glass frit 5 was performed in a similar manner to the first example.

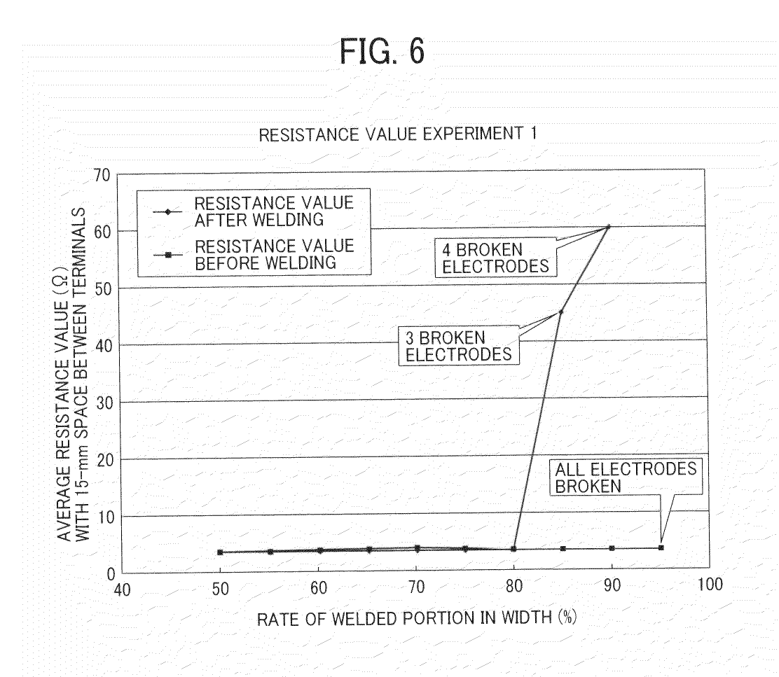

The electrodes on the bottom half of FIG. 5 on which the glass frit 5 was not welded are referred to as unwelded electrodes, and the electrodes on the top half of FIG. 5 on which the glass frit 5 was welded are referred to as welded electrodes. Terminals are applied to each of the electrodes with the distance of 15 mm to measure resistance values by performing I-V measurement. The mean values of the resistance values of the six electrodes are calculated, respectively. The results are depicted in FIG. 6.

As depicted in FIG. 6, no change was observed in resistance value between 50 to 80 percent in rate of welded portion in width, but beyond 80 percent in rate of welded portion in width, an abrupt increase in resistance value and breakage were observed. When the rate of welded portion in width was less than 50 percent in some samples, welding was unstable and very narrow in width at the corners and portions where the welding started. When a large number of samples were welded, it was observed that the sealing was unsuccessful.

[Resistance Value Experiment 2]

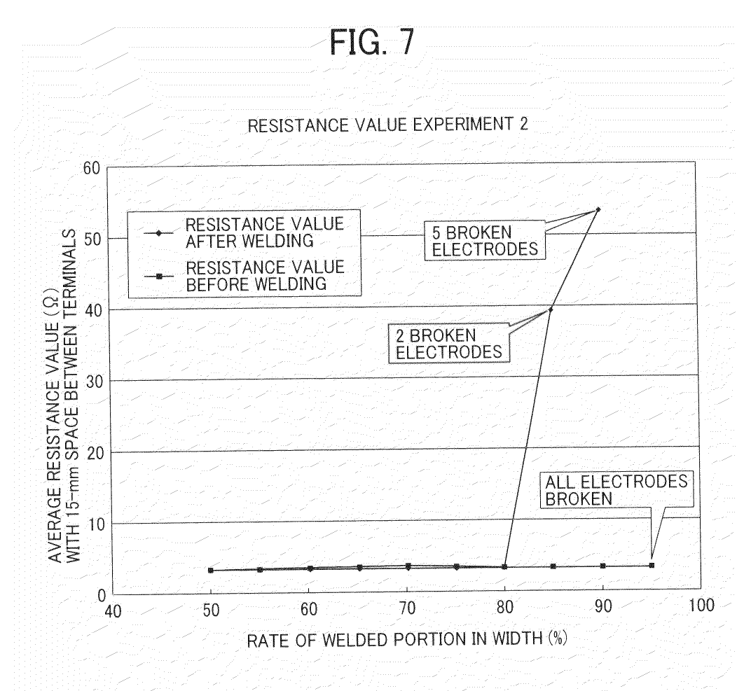

A cell as illustrated in FIG. 5 was produced in a similar manner to the resistance value experiment 1 described above, except that the first electrode 6 and the second electrode 7 are made of AgPdCu alloys instead of Al—Si—Cu alloys. Here, the composition of the AgPdCu alloys was Ag:Pd:Cu=98:1:1 in a similar manner to the second example. In a similar manner to FIG. 6 of the resistance value experiment 1, FIG. 7 depicts the results of calculating resistance values by performing I-V measurement.

As depicted in FIG. 7, no change was observed in resistance value between 50 to 80 percent in rate of welded portion in width, but beyond 80 percent in rate of welded portion in width, an abrupt increase in resistance value and breakage were observed. When the rate of welded portion in width was less than 50 percent in some samples, welding was unstable and very narrow in width at the corners and portions where the welding started. When a large number of samples were welded, it was observed that the sealing was unsuccessful.

[Resistance Value Experiment 3]

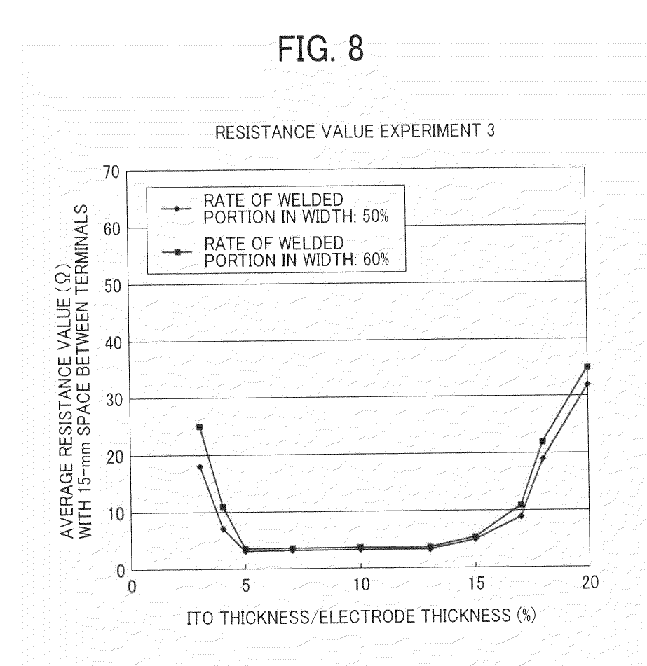

Next, in order to investigate how the rate of the thickness of the ITO layer 8 to the thickness of the first electrode 6 and the second electrode 7 influences the resistance value after welding, a cell similar to the cell fabricated in the resistance value experiment 1, except that the ratio of the thickness of the ITO layer 8 to the thickness of the first electrode 6 was varied, was fabricated. The welding power was controlled in the cells used in the resistance value experiment 3, and a cell whose rate of welded portion in width is 50 percent and a cell whose rate of welded portion in width is 60 percent were fabricated, respectively. FIG. 8 is a graph where the lateral axis indicates the ratio of the thickness of the ITO layer 8 to the thickness of the first electrode 6 and the vertical axis indicates the corresponding resistance value. In FIG. 8, the mean values of the resistance values of the six electrodes are calculated, respectively, in a similar manner to the resistance value experiment 1, and these mean values are plotted.

In FIG. 8, “ITO thickness/electrode thickness” indicates the ratio of the thickness of the ITO layer 8 to the thickness of the first electrode 6. When the ITO thickness/electrode thickness is less than 5 percent, there was no electrode breakage, but there were increases in resistance value. More specifically, the resistance value increased even when the rate of welded portion in width was reduced to 50 percent. The electrodes used in the resistance value experiment 3 were made of Al—Si—Cu alloys, and the ITO has a higher resistance value than the Al—Si—Cu alloy electrodes. Due to this configuration, there were increases in resistance value when the ITO thickness/electrode thickness became greater than 15 percent. It is considered that such increases were due to a high resistance value of the ITO in addition to the rate of welded portion in width. Further, exfoliation occurred at portions where the ITO thickness/electrode thickness was greater than 15 percent due to the stress difference among the electrodes, the ITO layer 8, and the glass frit 5.

[Resistance Value Experiment 4]

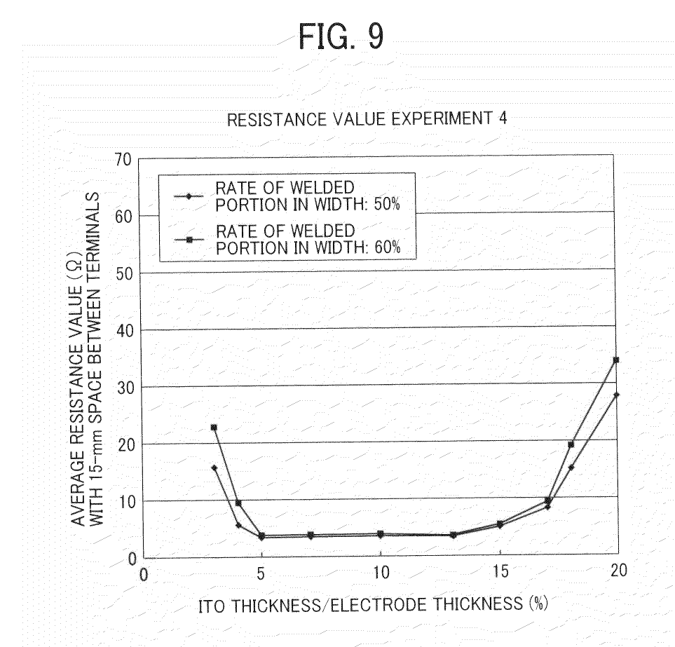

A cell as illustrated in FIG. 5 was produced in a similar manner to the third example described above, except that the first electrode 6 and the second electrode 7 are made of AgPdCu alloys instead of Al—Si—Cu alloys. Here, the composition of the AgPdCu alloys was Ag:Pd:Cu=98:1:1 in a similar manner to the second example. In a similar manner to FIG. 8 of the resistance value experiment 3, FIG. 9 is a graph where the lateral axis indicates the ratio of the thickness of the ITO layer 8 to the thickness of the first electrode 6 and the vertical axis indicates the corresponding resistance value.

As observed from FIG. 9, when the ITO thickness/electrode thickness was less than 5 percent, there was no electrode breakage, but there were increases in resistance value. More specifically, the resistance value increased even when the rate of welded portion in width was reduced to 50 percent. The electrodes used in the resistance value experiment 4 were made of AgPdCu alloy, and the ITO has a higher resistance value than the AgPdCu alloy electrodes. Due to this configuration, there were increases in resistance value when the ITO thickness/electrode thickness became greater than 15 percent. It is considered that such increases were due to a high resistance value of the ITO in addition to the rate of welded portion in width. Further, exfoliation occurred at portions where the ITO thickness/electrode thickness was greater than 15 percent due to the stress difference among the electrodes, the ITO layer 8, and the glass frit 5.

As described above, the organic EL display according to the example embodiments indicates characteristics of little electrode damage in laser welding, high luminous efficiency, and long useful life. In the description above, organic EL element packages (organic EL displays) are mainly described. However, no limitation is indicated to the organic EL element package, the organic EL display according to the example embodiments may be similarly applied to electric element packages used for other kinds of devices such as organic EL lighting and solar cells. In the description above, organic EL elements are described for example. However, no limitation is indicated thereby, and the organic EL display according to the example embodiments may be similarly applied to other kinds of electric elements where hermetic sealing is performed using a glass frit.

According to one aspect of the present invention, an electric element package can be provided in which high sealing strength is achieved and damage on an electrode can be reduced even when the electrode is irradiated with laser beam, without harming flexibility in design.

Numerous additional modifications and variations are possible in light of the above teachings. It is therefore to be understood that within the scope of the appended claims, the disclosure of the present invention may be practiced otherwise than as specifically described herein. For example, elements and/or features of different illustrative embodiments may be combined with each other and/or substituted for each other within the scope of this disclosure and appended claims.

What is claimed is:

1. An electric element package comprising:
an electrode formed on an element substrate and made of alloy whose main component is Al or Ag;
an ITO layer formed on the electrode;
an electric element formed on the electrode;
a sealing substrate arranged so as to face the element substrate; and
a glass frit formed between the sealing substrate and the ITO layer, the glass fit having a portion that contacts the ITO layer and a portion that contacts the sealing substrate, wherein the portion of the glass fit that contacts the ITO layer has width that is 50 to 80 percent of the portion of the glass frit that contacts the sealing substrate.

2. The electric element package according to claim 1, wherein the ITO layer has a thickness of 5 to 15 percent of the thickness of the electrode.

3. The electric element package according to claim 1, wherein
the electrode includes Al, Si, and Cu, and
Si and Cu account for 0.5 to 3.0 percent and 0.1 to 3.0 percent by weight, respectively, in the electrode.

4. The electric element package according to claim 1, wherein
the electrode includes Ag, Pd, and Cu, and
Pd and Cu account for 0.5 to 3.0 percent and 0.1 to 3.0 percent by weight, respectively, in the electrode.

5. The electric element package according to claim 1, wherein the electric element is an organic EL element.
